(19) United States
(12) Patent Application Publication
(10) Pub. No.: US 2024/0414933 A1
(43) Pub. Date: Dec. 12, 2024

(54) METHOD OF OBSERVING AUGER RECOMBINATION OF QUANTUM DOTS

(71) Applicants: Samsung Display Co., LTD., Yongin-si Gyeonggi-do (KR); Seoul National University R&DB Foundation, Seoul (KR)

(72) Inventors: YUNHYUK KO, Yongin-si (KR); CHANGHEE LEE, Yongin-si (KR); Harkjune LEE, Suwon-si (KR); Kookheon CHAR, Seoul (KR)

(21) Appl. No.: 18/442,156

(22) Filed: Feb. 15, 2024

(30) Foreign Application Priority Data
Jun. 7, 2023 (KR) 10-2023-0072771

(51) Int. Cl. H10K 50/115; H10K 50/15; H10K 50/16; H10K 102/00

(52) U.S. Cl. CPC H10K 50/115; H10K 50/157; H10K 50/167; H10K 2102/351

(57) ABSTRACT

A method of observing Auger recombination of quantum dots in an Electron-Only Device (EOD) including preparing an EOD device, wherein the EOD device includes quantum dots, applying a current to the EOD device and observing negative trions formed in the EOD device. Additionally, a method of observing Auger recombination of quantum dots in a Hole-Only Device (HOD) including preparing an HOD device, wherein the HOD device includes quantum dots, applying a current to the HOD device and observing positive trions formed in the HOD device.

This application claims priority to Korean Patent Application No. 10-2023-0072771, filed on Jun. 7, 2023, and all the benefits accruing therefrom under 35 U.S.C. § 119, the entire content of which in its entirety is herein incorporated by reference.

### BACKGROUND

### (a) Field of the Invention

The invention relates to a method for observing Auger recombination of quantum dots, and more particularly to methods for observing Auger recombination of quantum dots in an Electron-Only Device (EOD) and a Hole-Only Device (HOD).

### (b) Description of the Related Art

The light emitting device includes an anode, a cathode, and a light emitting layer formed between them. The light is emitted when the exciton, formed by the combination of the hole injected from the anode and the electron injected from the cathode in the light emitting layer, falls from an excited state to the ground state.

Since the light emitting device can be operated at low voltage and can be configured in a lightweight flat form, due to its excellent characteristics, such as viewing angle, contrast, response speed, etc., its range of applications is expanding, from personal portable devices to televisions.

Auger recombination may occur in the process of forming an exciton in a light emitting device.

Auger recombination is a phenomenon in which light is not emitted to the outside and energy is transferred to other excitons in the vicinity when electrons and holes combine.

That is, since light is not emitted, it becomes a major obstacle to improving the efficiency of light emitting devices based on quantum dots, especially on displays.

### SUMMARY

Embodiments of the invention provide a method for observing Auger recombination of quantum dots through observation of negative trions or positive trions.

In an embodiment, a method for observing Auger recombination of quantum dots includes preparing an electron-only device (EOD), applying a current to the EOD device, and observing negative trions formed in the EOD device.

In an embodiment, in the step of applying the current to the EOD device, the applied current may be about 0.5 A/cm² or less.

In an embodiment, observation of the negative trion formed in the EOD device may be performed by comparing the photoluminescence (PL) intensity of the EOD device before and after applying the current.

In an embodiment, the EOD device may include a first electrode and a second electrode disposed to be facing each other, a light emitting layer located between the first electrode and the second electrode, a first electron transport layer located between the first electrode and the light emitting layer, and a second electron transport layer located between the second electrode and the light emitting layer.

In an embodiment, the light emitting layer may have a thickness of about 300 Å to about 500 Å.

In an embodiment, the first electron transport layer and the second electron transport layer may include different materials.

In an embodiment, the first electron transport layer and the second electron transport layer may include the same materials.

In an embodiment, the quantum dots may include one or more selected from CdSe/CdS, CdS/CdSe/CdS, CdSe/Cd1-xZnXSe/CdZnS, and ZnSe1-xTeX/ZnSe/ZnS.

In an embodiment, the first electron transport layer may include ZnO.

In an embodiment, the second electron transport layer may include TPBi.

In an embodiment, a method for observing Auger recombination of quantum dots includes preparing a hole-only device (HOD), applying a current to the HOD device, and observing positive trions formed in the HOD device.

In an embodiment, in the step of applying the current to the HOD device, the applied current may be about 0.5 A/cm² or less.

In an embodiment, observation of the positive trions formed in the HOD device may be performed by comparing the PL intensity of the HOD device before and after applying the current.

In an embodiment, the HOD element includes a first electrode and a second electrode disposed to be facing each other, a light emitting layer positioned between the first electrode and the second electrode, a first hole transport layer positioned between the first electrode and the light emitting layer, and a second hole transport layer positioned between the second electrode and the light emitting layer.

In an embodiment, the light emitting layer may have a thickness of about 300 Å to about 500 Å.

In an embodiment, the first hole transport layer and the second hole transport layer may include different materials.

In an embodiment, the first hole transport layer and the second hole transport layer may include the same materials.

In an embodiment, the quantum dots may include one or more selected from CdSe/CdS, CdS/CdSe/CdS, CdSe/Cd1-xZnXSe/CdZnS, and ZnSe1-xTeX/ZnSe/ZnS.

In an embodiment, the first hole transport layer may include PEDOT: PSS and TFB.

In an embodiment, the second hole transport layer may include CBP.

According to embodiments, a method for observing Auger recombination of quantum dots through observation of negative trions or positive trions is provided.

### BRIEF DESCRIPTION OF THE DRAWINGS

FIG. 1 shows a stacked structure of an EOD device, according to an embodiment.

FIG. 2 illustrates an observation of an Auger recombination process using an EOD device, according to an embodiment.

FIG. 3 shows an energy band diagram illustrating electron movement in the EOD device of FIG. 2, according to an embodiment.

FIG. 4 is a graph illustrating a measurement of a PL intensity before operation and after being charged in an EOD device, according to an embodiment.

FIG. 5 illustrates a laminated structure of an HOD device, according to an embodiment.

FIG. 6 illustrates an observation of an Auger recombination process using an HOD device, according to an embodiment.

FIG. 7 shows an energy band diagram of the HOD device of FIG. 6 and the movement of the charge, according to an embodiment.

FIG. 8 shows a graph of a measurement of a PL intensity before operation and after charging of an HOD device, according to an embodiment.

FIG. 9 shows a graph of negative trions measured using the EOD device and positive trions measured using the HOD device, according to an embodiment.

### DETAILED DESCRIPTION

Hereinafter, various embodiments of the invention are described in detail so that a person of ordinary skill in the art can easily carry it out, referring to the attached drawings.

The invention can be implemented in various different forms and is not limited to the examples described herein.

In order to clearly explain the invention, parts unrelated to the explanation have been omitted, and the same reference symbols are attached to identical or similar constituent elements throughout the entire specification.

In addition, since the size and thickness of each component shown in the drawings are arbitrarily shown for convenience of explanation, the invention is not limited to that which is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, or plate is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being positioned above or below the reference part and does not necessarily mean being positioned “above” or “on” it in the opposite direction of gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

In addition, throughout the specification, when a certain component is said to “include,” it may further include other components without excluding other components unless otherwise stated.

In addition, throughout the specification, when reference is made to a “planar image,” it means when the target part is viewed from above, and when reference made to a “cross-sectional image,” it means when a cross-section of the target part cut vertically is viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the invention.

Hereinafter, a method for observing Auger recombination of quantum dots according to an embodiment will be described.

In the method for observing Auger recombination of quantum dots according to an embodiment, Auger recombination of quantum dots is observed using an electron-only device (EOD) or a hole-only device (HOD).

The EOD element will be described below.

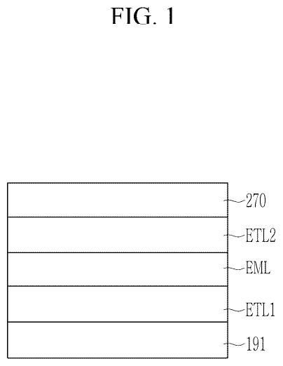

FIG. 1 shows a stacked structure of an EOD device, according to an embodiment.

In an embodiment and referring to FIG. 1, the EOD device includes a first electrode 191, a second electrode 270, and a light emitting layer (EML) positioned between the first electrode 191 and the second electrode 270.

Also, in an embodiment, the first electron transport layer (ETL1) is positioned between the first electrode 191 and the light emitting layer (EML), and the second electron transport layer (ETL2) is positioned between the second electrode 270 and the light emitting layer (EML).

In other words, according to an embodiment, the EOD device has electron transport layers (ETL1, ETL2) positioned on both sides of the light emitting layer (EML).

In an embodiment, the first electron transport layer (ETL1) and the second electron transport layer (ETL2) can include different materials, or they can include the same materials.

In an embodiment, the first electrode 191 may include a transparent conductive oxide.

In an embodiment, the first electrode 191 may include Indium Tin Oxide (ITO).

In an embodiment, the second electrode 270 may include one or more metals or their alloys such as magnesium, calcium, sodium, potassium, titanium, indium, yttrium, lithium, gadolinium, aluminum, silver, tin, lead, cesium, barium, etc., or multilayer structured materials such as LiF/Al, LiO₂/Al, LiF/Ca, LiF/Al and MoOx/Al, but is not limited to these.

In an embodiment, the second electrode 270 can be an LiF/Al laminated structure or a MoOx/Al laminated structure, wherein x may be 1 to 4.

In an embodiment, the light emitting layer EML may include quantum dots.

In an embodiment, the diameter of the quantum dots may be, for example, about 1 nm to about 10 nm.

In an embodiment, the quantum dots may be synthesized by a wet chemical process, an organometallic chemical vapor deposition process, a molecular beam epitaxy process, or a process similar thereto.

In an embodiment, the wet chemical process is a method of growing quantum dot particle crystals after mixing an organic solvent and a precursor material.

In an embodiment, when the crystal grows, the organic solvent naturally plays the role of a dispersant coordinated on the quantum dot crystal surface and regulates the growth of the crystals. Therefore, it is more convenient than vapor deposition methods such as Metal Organic Chemical Vapor Deposition (MOCVD) or Molecular Beam Epitaxy (MBE), and through a low-cost process, the growth of quantum dot particles can be controlled.

In an embodiment, quantum dots are Group III-VI semiconductor compounds, Group II-VI semiconductor compounds, Group III-V semiconductor compounds, Group I-III-VI semiconductor compounds, Group IV-VI semiconductor compounds, Group IV elements or compounds, or any combination thereof.

In an embodiment, examples of Group II-VI semiconductor compounds include binary element compounds such as CdS, CdSe, CdTe, ZnS, ZnSe, ZnTe, ZnO, HgS, HgSe, HgTe, MgSe, MgS and the like, ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc., quaternary compounds such as CdZnSeS, CdZnSeTe, CdZnSTe, CdHgSeS, CdHgSeTe, CdHgSTe, HgZnSeS, HgZnSeTe, HgZnSTe and the like or any combination thereof.

Moreover, in an embodiment, examples of Group III-V semiconductor compounds include binary element compounds such as GaN, GaP, GaAs, GaSb, AlN, AlP, AlAs, AlSb, InN, InP, InAs, InSb, and the like, ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAINP and the like, quaternary compounds such as GaAINAs, GaAINSb, GaAlPAs, GaAlPSb, GaInNP, GaInNAs, GaInNSb, GaInPAs, GaInPSb, InAINP, InAINAs, InAINSb, InAlPAs, InAlPSb and the like, or any combination thereof.

Meanwhile, in an embodiment, group III-V semiconductor compounds may further include a Group II element.

In an embodiment, examples of Group III-V semiconductor compounds further including a Group II element may include InZnP, InGaZnP, InAlZnP, and the like.

In an embodiment, examples of Group III-VI semiconductor compounds include binary element compounds such as GaS, Ga2S3, GaSe, Ga2Se3, GaTe, InS, InSe, In2Se3, InTe and the like, ternary compounds such as InGaS3 and InGaSe3 and the like or any combination thereof.

In an embodiment, examples of Group I-III-VI semiconductor compounds include three-element compounds such as AgInS, AgInS2, AgInSe2, AgGaS, AgGaS2, AgGaSe2, CuInS, CuInS2, CulnSe2, CuGaS2, CuGaSe2, CuGaO2, AgGaO2, AgAlO2, and the like, quaternary compounds such as AgInGaS2 and AgInGaSe2 and the like, or any combination thereof.

In an embodiment, examples of Group IV-VI semiconductor compounds include binary element compounds such as SnS, SnSe, SnTe, PbS, PbSe, PbTe and the like, ternary compounds such as SnSeS, SnSeTe, SnSTe, PbSeS, PbSeTe, PbSTe, SnPbS, SnPbSe, SnPbTe and the like, quaternary compounds such as SnPbSSe, SnPbSeTe, and SnPbSTe and the like or any combination thereof.

In an embodiment, the Group IV element or compound may be a single element compound such as Si, Ge, or the like, binary elemental compounds such as SiC, SiGe, and the like or any combination thereof.

In an embodiment, each element included in the multi-element compound such as the binary element compound, the ternary element compound, and the quaternary element compound may be present in the particles at a uniform concentration or a non-uniform concentration.

That is, in an embodiment, the chemical formula means the types of elements included in the compound, and the element ratios in the compound may be different.

For example, in an embodiment, AgInGaS₂ may mean AgInₓGa1-ₓS₂ (where ₓ is a real number between 0 and 1).

On the other hand, in an embodiment, the quantum dots may have a single structure in which the concentration of each element included in the quantum dots is uniform or is a dual core-shell structure.

For example, in an embodiment, a material included in the core and a material included in the shell may be different from each other.

In an embodiment, the shell of the quantum dots may serve as a protective layer for maintaining semiconductor properties by preventing chemical deterioration of the core and/or as a charging layer for imparting electrophoretic properties to the quantum dots.

In an embodiment, the shell may be monolayer or multilayer.

In an embodiment, the interface between the core and the shell may have a concentration gradient in which the concentration of elements present in the shell decreases toward the center.

In an embodiment, examples of the quantum dot shell include metal or non-metal oxides, semiconductor compounds, or combinations thereof.

In an embodiment, examples of the metal or nonmetal oxide include binary element compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, ternary compounds such as MgAl₂O₄, CoFe₂O₄, NiFe₂O₄, CoMn₂O₄, and the like or any combination thereof.

In an embodiment, examples of the semiconductor compound include a Group III-VI semiconductor compound as described herein, Group II-VI semiconductor compounds, Group III-V semiconductor compounds, Group III-VI semiconductor compounds, Group I-III-VI semiconductor compounds, Group IV-VI semiconductor compounds, or any combination thereof.

For example, in an embodiment, the semiconductor compound may be CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or any combination thereof.

In an embodiment, each element included in the multi-element compound such as the two-element compound or the three-element compound may be present in the particles at a uniform or non-uniform concentration.

That is, in an embodiment, the chemical formula means the type of elements included in the compound, and the element ratios in the compound may be different.

In an embodiment, the quantum dots may include one or more of CdSe/CdS, CdSe/Cd1-_{X}Zn_{X}Se/CdZnS, and ZnSe1-_{X}Te_{X}/ZnSe/ZnS, wherein the ₓ may be a real number between 0 and 1.

In an embodiment, it is preferable that the thickness of the light emitting layer (EML) not have three or more quantum dots.

That is, in an embodiment, the light emitting layer (EML) may have a thickness of about 300 Å to about 500 Å.

In an embodiment, when the light emitting layer (EML) is thick, current flow is hindered during measurement for observing Auger recombination, which is not preferable. In an embodiment, the first electron transport layer (ETL1) and the second electron transport layer (ETL2) may include ZnO or TPBi (2,2′,2″-(1,3,5-Benzinetriyl)-tris (1-phenyl-1-H-benzimidazole), but are not limited to these.

In an embodiment, other materials may be used as long as they have a material having an energy level similar to that of ZnO or a material having an energy level similar to that of TPBi.

In an embodiment, through the process of injecting charge into the EOD device, Auger recombination can be observed without deterioration of the characteristics of the quantum dots.

In an embodiment, auger recombination is a phenomenon in which light is not emitted to the outside and energy is transferred to other excitons in the vicinity when electrons and holes combine.

That is, in an embodiment, since light does not come out, it becomes a major obstacle to improving the efficiency of light emitting devices based on quantum dots, especially with displays.

In an embodiment, measuring the degree of Auger recombination is important for measuring the efficiency of a light emitting device.

Accordingly, in an embodiment, the method for observing auger recombination including observing Auger recombination of quantum dots using an electron-only device (EOD) or a hole-only device (HOD).

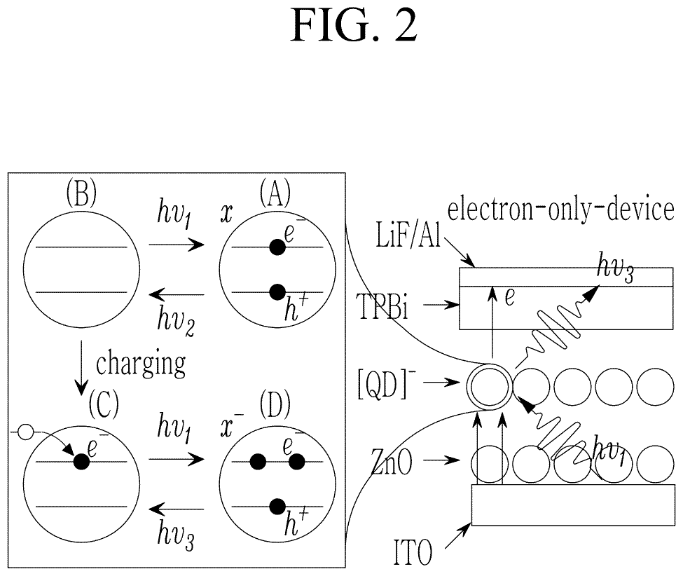

FIG. 2 illustrates an observation process of Auger recombination using the EOD device, according to an embodiment.

FIG. 2 shows an EOD device having stacked structure of ITO/ZnO/QD/TPBi/LiF/Al, according to an embodiment.

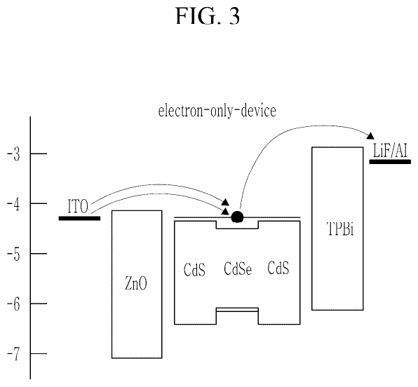

FIG. 3 shows an energy band diagram and electron movement of the EOD device of FIG. 2, according to an embodiment.

In an embodiment and referring to FIG. 2, when electrons are injected into the EOD device, the light emitting layer (EML) is charged.

In an embodiment, in this electron-injected and charged state, light is irradiated from the outside.

In an embodiment, light irradiation may be performed using a laser.

In an embodiment, by such light irradiation, negative trions are formed as shown in state (D) of FIG. 2.

In an embodiment, a negative trion means two electrons and one hole.

In an embodiment, the degree of Auger recombination can be measured by observing the negative trions thus formed.

In an embodiment, after formation of the negative trions, light emission may be performed, and the degree of Auger recombination may be measured by measuring the degree of light emission.

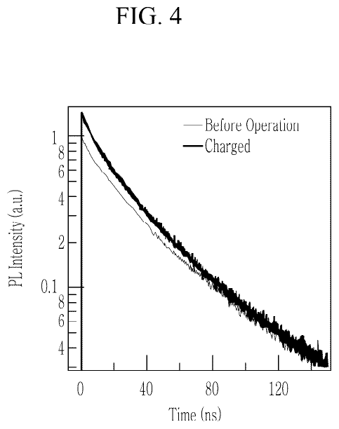

FIG. 4 is a graph of measurement of PL intensity before operation and after operation (charged) of the EOD device, according to an embodiment.

In an embodiment and referring to FIG. 4, the degree of recombination of defects can be measured through the difference in PL intensity (photoluminescence) before operation and after charging.

In an embodiment as shown in FIG. 4, the PL intensity before operation is the measurement of luminescence in the process indicated by hv2 in FIG. 2, and the PL intensity after operation is the measurement of luminescence in the process indicated by hv2 and hv3 in FIG. 2.

Therefore, through this comparison, it is possible to measure the degree of luminescence in the process denoted by hv3, according to an embodiment.

Among conventional Auger recombination analysis methods, photochemical and electrochemical methods have a problem in that they cannot accurately observe multi-exciton dynamics due to chemical reactions occurring on the surface in addition to injecting additional charges.

However, the method for observing Auger recombination according to an embodiment can observe the degree of Auger recombination without surface chemical reaction.

In addition, the conventional optical doping method could not observe the positive trions, but in an embodiment of the invention, there is an advantage in that the positive trions can be observed using the HOD device.

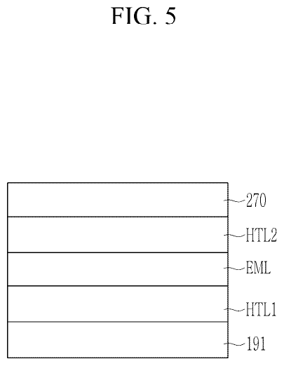

FIG. 5 shows a stacked structure of the HOD device, according to an embodiment. In an embodiment and referring to FIG. 5, the HOD device includes a first electrode 191, a second electrode 270, and a light-emitting layer (EML) positioned between the first electrode 191 and the second electrode 270.

Also, in an embodiment, the first hole transport layer (HTL1) is positioned between the first electrode 191 and the light emitting layer (EML), and the second hole transport layer (HTL2) is positioned between the second electrode 270 and the light emitting layer (EML).

In other words, in an embodiment, the hole transport layers (HTL1, HTL2) are positioned on both sides of the light emitting layer (EML).

In an embodiment, the first hole transport layer (HTL1) and the second hole transport layer (HTL2) may contain different materials, or they may contain the same materials.

In an embodiment, the description of the first electrode 191, the second electrode 270, and the emission layer (EML) is the same as in FIG. 1.

A detailed description of the same constituent element is omitted.

In an embodiment, the first hole transport layer (HTL1) and the second hole transport layer (HTL2) may include one or more of PEDOT: PSS, TFB (Poly [(9,9-dioctylfluorenyl-2,7-diyl)-co-(4,4′-(N-(4-sec-butylphenyl)diphenylamine)]), and CBP (4,4′-Bis(N-carbazolyl)-1,1′-biphenyl), but are not limited to these.

In an embodiment, through the process of injecting charges into the HOD device, Auger recombination can be observed without deterioration of the characteristics of the quantum dots.

In addition, in an embodiment, through the charge injection of the HOD device, it is possible to observe positive trions, which have been difficult to observe in the past.

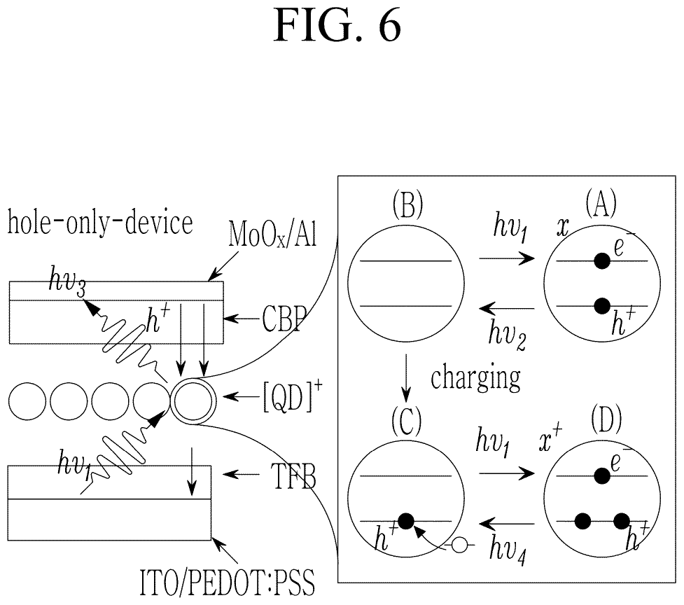

FIG. 6 illustrates an observation process of Auger recombination using a HOD device, according to an embodiment.

FIG. 6 shows an embodiment of an HOD device having a stacked structure of ITO/PEDOT: PSS/TFB/QD/CBP/MoOx/Al.

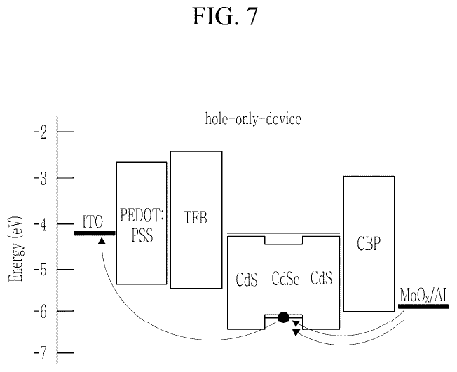

FIG. 7 shows an energy band diagram and charge movement of the HOD device of FIG. 6, according to an embodiment.

Referring to FIG. 6, when charges are injected into the HOD element, the light emitting layer (EML) is charged.

In an embodiment, in this electron-injected and charged state, light is irradiated from the outside.

In an embodiment, light irradiation may be performed using a laser.

In an embodiment, by such light irradiation, positive trions are formed as shown in state (D) of FIG. 6.

In an embodiment, a positive trion means two holes and one charge.

Therefore, the degree of Auger recombination can be measured by observing the positive trions thus formed, according to an embodiment.

In an embodiment, after formation of the positive trions, light emission may be performed, and the degree of Auger recombination may be measured by measuring the degree of light emission.

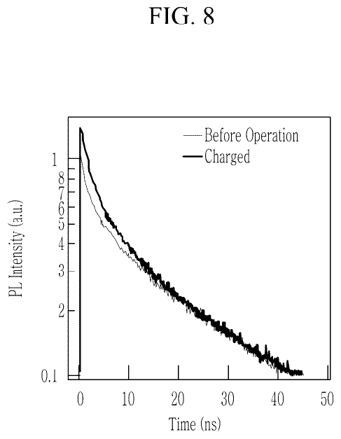

FIG. 8 shows a graph of PL intensity measurements before operation and after operation (charged) of the HOD device, according to an embodiment.

In an embodiment and referring to FIG. 8, the degree of Auger recombination can be measured through the difference in PL intensities before operation and after operation (charged).

In an embodiment, in FIG. 6, the PL intensity before operation is the measurement of luminescence in the process indicated by hv2 in FIG. 6, and the PL intensity after operation is the measurement of luminescence in the process indicated by hv2 and hv4 in FIG. 6.

Therefore, through this comparison, it is possible to measure the degree of luminescence in the process denoted by hv4, according to an embodiment.

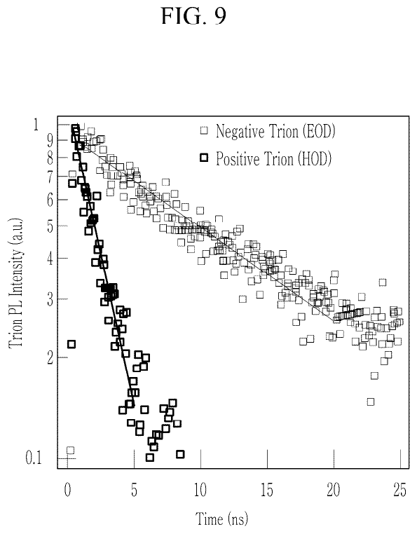

FIG. 9 is a graph illustrating negative trions measured using the EOD device according to an embodiment and positive trions measured using the HOD device according to an embodiment.

It was confirmed through FIG. 9 that negative trions and positive trions can be observed using the EOD device and the HOD device according to an embodiment.

Through this, Auger recombination of a light emitting device including quantum dots can be measured, according to an embodiment.

In particular, positive trions could not be observed in the case of the existing Auger recombination measurement method, but in an embodiment, the amount of positive trions could be observed.

Also, the quantum dots of the ZnSe_{1-X}Te_{X} series with a high conduction band of the luminescent layer had a very unstable negative trion state and could not be observed with conventional methods. However, in an embodiment, due to the high energy level of TPBi, which is an electron transport layer, electrons are confined to the quantum dot layer, allowing the observation of negative trions.

In an embodiment, the device was manufactured and used with a thickness of ZnO of about 20 nm, TPBi of about 30 nm, MoOx of about 10 nm, PEDOT: PSS of about 20 nm, TFB of about 20 nm, CBP of about 60 nm and Al of about 110 nm, but the thickness of each layer is not limited thereto.

In an embodiment, it is preferable that the thickness of each layer except for the first electrode and the second electrode not exceed about 100 nm.

In addition, when measuring Auger recombination according to an embodiment, an excessively high current may destroy the EOD or HOD device, and the applied current is preferably about 0.5 A/cm² or less.

If the applied current is more than 0.5 A/cm², it is not preferable because the EOD element or the HOD element may be destroyed.

While the invention has been particularly shown and described with reference to embodiments thereof, it will be understood by those of ordinary skill in the art that various changes in form and details may be made therein without departing from the spirit or scope of the invention. Therefore, it is to be understood that the foregoing is illustrative of various embodiments and is not to be construed as limited to the specific embodiments disclosed, and that modifications to the invention, are intended to be included within the scope of the invention. Moreover, the embodiments or parts of the embodiments may be combined in whole or in part without departing from the scope of the invention.

What is claimed is:

1. A method of observing Auger recombination of quantum dots in an Electron-Only Device (EOD), comprising:
preparing an Electron-Only Device (EOD) device, wherein the EOD device includes quantum dots;
applying a current to the EOD device; and
observing negative trions formed in the EOD device.

2. The method of claim 1, wherein
applying a current includes applying a current of about 0.5 Å/cm² or less to the EOD device.

3. The method of claim 1, wherein
observing negative trions includes comparing a photoluminescence (PL) intensity of the EOD device before and after applying the current to the EOD device.

4. The method of claim 1, wherein
the EOD device comprises:
a first electrode and a second electrode disposed to be facing each other;
a light emitting layer positioned between the first electrode and the second electrode;
a first electron transport layer positioned between the first electrode and the light emitting layer; and
a second electron transport layer positioned between the second electrode and the light emitting layer.

5. The method of claim 4, wherein
the light emitting layer has a thickness in the range of about 300 Å to about 500 Å.

6. The method of claim 4, wherein
the first electron transport layer and the second electron transport layer include different materials.

7. The method of claim 4, wherein
the first electron transport layer and the second electron transport layer include the same material.

8. The method of claim 4, wherein
the quantum dots include at least one selected from CdSe/CdS, CdS/CdSe/CdS, CdSe/Cd_{1-X}Zn_{X}Se/CdZnS, and ZnSe_{1-X}Te_{X}/ZnSe/ZnS.

9. The method of claim 8, wherein
the first electron transport layer includes ZnO.

10. The method of claim 9, wherein
the second electron transport layer includes TPBi.

11. A method of observing Auger recombination of quantum dots in a Hole-Only Device (HOD), comprising, comprising:
preparing an HOD device, wherein the HOD device includes quantum dots;
applying a current to the HOD device; and
observing positive trions formed in the HOD device.

12. The method of claim 11, wherein:
applying a current includes applying a current of about 0.5 Å/cm² or less to the HOD device.

13. The method of claim 11, wherein
observing positive trions includes comparing a photoluminescence (PL) intensity of the HOD device before and after applying the current to the HOD device.

14. The method of claim 11, wherein
the HOD element comprises:
a first electrode and a second electrode disposed to be facing each other;
a light emitting layer positioned between the first electrode and the second electrode;
a first hole transport layer positioned between the first electrode and the light emitting layer; and
a second hole transport layer positioned between the second electrode and the light emitting layer.

15. The method of claim 14, wherein
the light emitting layer has a thickness range of about 300 Å to about 500 Å.

16. The method of claim 14, wherein
the first hole transport layer and the second hole transport layer include different materials.

17. The method of claim 14, wherein
the first hole transport layer and the second hole transport layer include the same materials.

18. The method of claim 14, wherein
the quantum dots include at least one selected from CdSe/CdS, CdS/CdSe/CdS, CdSe/Cd1-XZnXSe/CdZnS, and ZnSe1-XTeX/ZnSe/ZnS.

19. The method of claim 18, wherein
the first hole transport layer includes PEDOT: PSS and TFB.

20. The method of claim 19, wherein
the second hole transport layer includes CBP.
